(19) United States
(12) Patent Application Publication
(10) Pub. No.: US 2025/0324631 A1
(43) Pub. Date: Oct. 16, 2025

(54) METHOD FOR MANUFACTURING GAN HEMT POWER SEMICONDUCTOR EPITAXIAL WAFERS WITH HIGH-QUALITY GAN CHANNEL REGION THROUGH GROWTH TEMPERATURE MODULATION

(71) Applicant: WAVELORD CO., LTD., Gyeonggi-do (KR)

(72) Inventors: June O SONG, Gyeonggi-do (KR); Hyun Chul LIM, Gyeonggi-do (KR); Young Hun HAN, Gyeonggi-do (KR); Hyung Sun YUN, Gyeonggi-do (KR)

(21) Appl. No.: 19/176,519

(22) Filed: Apr. 11, 2025

(30) Foreign Application Priority Data
Apr. 12, 2024 (KR) 10-2024-0049576
Feb. 3, 2025 (KR) 10-2025-0013144

(51) Int. Cl. H10D 30/01; C30B 25/18; C30B 29/38; C30B 29/40; H01L 21/02

(52) U.S. Cl. CPC H10D 30/015; C30B 25/183; C30B 29/38; C30B 29/403; C30B 29/406; H01L 21/0217; H01L 21/02458; H01L 21/0254

(57) ABSTRACT

Embodiments according to the present invention provide a high-quality GaN HEMT power semiconductor epitaxy wafer having a three-dimensional nitride structure, comprising: a growth substrate; a nucleation region formed on the growth substrate; and a three-dimensional nitride structure region formed on the nucleation region and having a composition ratio that varies along a lateral direction.

### CROSS-REFERENCE TO RELATED APPLICATIONS

This application claims priority to Korean Patent Application Nos. 10-2024-0049576, filed on Apr. 12, 2024 and 10-2025-0013144, filed on Feb. 3, 2025. The entire disclosure of the applications identified in this paragraph is incorporated herein by reference.

### FIELD

The present invention relates to a method for manufacturing a GaN HEMT power semiconductor epitaxy wafer, and is characterized in that the performance and quality of a GaN HEMT power semiconductor device are dramatically improved by reducing crystal defects in a channel region and minimizing vertical or horizontal leakage current through modulation of the growth temperature.

### BACKGROUND

The GaN HEMT power semiconductor epitaxy structure typically has a structure in which a nucleation region, a stress-relieving region, a buffer region, a channel region, and a barrier region are sequentially stacked on a growth substrate.

The channel region and barrier region function as key active regions of GaN HEMT power semiconductor devices.

The substructures, namely nucleation region, stress-relieving region, and buffer region, are provided to minimize crystal defects in the active region, prevent leakage current, and ensure effective heat dissipation.

The nucleation region, which promotes the formation of high-quality buffer regions and active regions, is proposed to be formed of AIN.

The stress-relieving region is a region that prevents bowing or cracking of the wafer caused by the subsequently grown buffer region and active region, and it is proposed to control the composition of gallium (Ga).

The buffer region is a current blocking region that reduces vertical leakage current by imparting high-resistive properties, and achieves a given purpose with GaN material doped with carbon (C) or iron (Fe) as a dopant (C- or Fe-doped GaN).

However, when growing C- or Fe-doped GaN, the quality of the GaN crystal deteriorates, and since it is formed thickly for high-resistance properties, there is a problem of hindering heat dissipation generated when driving GaN HEMT power semiconductor devices, thereby deteriorating the device characteristics.

Therefore, the development of a buffer region that has excellent heat dissipation performance while possessing high crystal quality and high resistance properties is required.

### SUMMARY

### Technical Problem

The present invention aims to provide a method for manufacturing a GaN HEMT power semiconductor epitaxy wafer capable of forming a high-quality active region by minimizing crystal defects (threading dislocations) that originate from a growth substrate and propagate in the growth direction.

The present invention aims to provide a method for manufacturing a GaN HEMT power semiconductor epitaxy wafer capable of maximizing the heat dissipation characteristics of a GaN HEMT power semiconductor device.

The present invention aims to provide a method for manufacturing a GaN HEMT power semiconductor epitaxy wafer, which secures a high-quality channel region with a reduced thickness of the device and maximizes the heat dissipation characteristics of the device by forming a channel region directly on a nucleation region instead of a conventional Fe or C doped high-resistivity GaN buffer region.

### Technical Solution

Embodiments according to the present invention comprise: a step of growing an AlN nucleation region formed on a growth substrate; a step of growing a first GaN channel region formed on the AlN nucleation region at a first growth temperature higher than a growth temperature of the AlN nucleation region; a step of growing a second GaN channel region formed on the first GaN channel region at a second growth temperature lower than the first growth temperature; a step of growing a third GaN channel region formed on the second GaN channel region at a third growth temperature equal to or higher than the first growth temperature; and a step of forming an AlGaN barrier region on the third GaN channel region.

Embodiments according to the present invention may further comprise a step of growing an MT-GaN channel region at an MT growth temperature that is higher than the second growth temperature and lower than the third growth temperature, wherein the MT-GaN channel region is formed to be inserted between the second GaN channel region and the third GaN channel region.

Embodiments according to the present invention may further comprise a step of forming a SiNx region that is formed to be inserted between the first GaN channel region and the second GaN channel region, and that stops growth of the first GaN channel region and masks crystal defects on a surface of the first GaN channel region.

In embodiments according to the present invention, the step of forming the SiNₓ region is a step of forming nanoscale SiNₓ in a 3-dimensional growth mode by stopping the growth of the first GaN channel region and supplying SiH₄ or Si₂H₆, which is a Si source, under conditions in which ammonia (NH₃), which is a nitrogen source, is supplied.

In embodiments according to the present invention, the step of growing the AlN nucleation region may comprise a first nucleation region growth step of supplying only TMAl or TEAl as an Al source without supplying ammonia (NH₃) as a nitrogen source at a temperature lower than a growth temperature of the AlN nucleation region; a second nucleation region growth step of supplying ammonia (NH₃) as a nitrogen source to the first nucleation region growth step and growing AlN in a 3-dimensional growth mode; and a third nucleation region growth step of increasing the temperature to the growth temperature of the AlN nucleation region and growing AlN in a 2-dimensional growth mode.

In embodiments according to the present invention, the step of growing the first GaN channel region may be to grow GaN in a 2-dimensional growth mode at the first growth temperature.

In embodiments according to the present invention, the step of growing the second GaN channel region may be to relieve stress generated by the first growth temperature, which is a high temperature, in the growth of the first GaN channel region, increase the thickness, and minimize crystal defects.

In embodiments according to the present invention, the step of growing the third GaN channel region may improve the crystallinity of the first, second, and third GaN channel regions or the first, second, third, and MT GaN channel regions.

In embodiments according to the present invention, the first growth temperature may be 1050 to 1100° C., the second growth temperature may be 750 to 850° C., the third growth temperature may be 1050 to 1100° C., and the MT growth temperature may be 850 to 950° C.

### Advantageous Effects

According to the present invention, the thickness of the device can be formed thinly by forming a plurality of GaN channel regions having differences in growth temperatures that replace the buffer region of conventional high-resistance GaN (Fe or C doped), thereby improving the crystal quality and maximizing the heat dissipation characteristics of the device.

According to the present invention, by dividing the AlN nucleation region into three stages and growing it, the nitride parasitic reaction can be suppressed, smooth and uniform Al surface polarity can be promoted, and the generation of V-pit shaped surface crystal defects can be suppressed.

### BRIEF DESCRIPTION OF DRAWINGS

FIG. 1 is a drawing for explaining a method for manufacturing a GaN HEMT power semiconductor epitaxy wafer according to one embodiment of the present invention.

FIG. 2 is a drawing showing a modified example of FIG. 1.

FIG. 3 is a drawing for explaining a method for manufacturing a GaN HEMT power semiconductor epitaxy wafer according to another embodiment of the present invention.

FIG. 4 is a drawing showing a modified example of FIG. 3.

FIG. 5 is a drawing for explaining a method for manufacturing a nucleation region in FIGS. 1 and 2.

### DETAILED DESCRIPTION

Hereinafter, a method for manufacturing a GaN HEMT power semiconductor epitaxy wafer having a high-quality GaN channel region through growth temperature modulation according to embodiments of the present invention will be described in detail with reference to the drawings.

The terms used below have been selected for convenience of explanation, and should be appropriately interpreted in a meaning that is consistent with the technical idea of the present invention without being limited to the dictionary meaning.

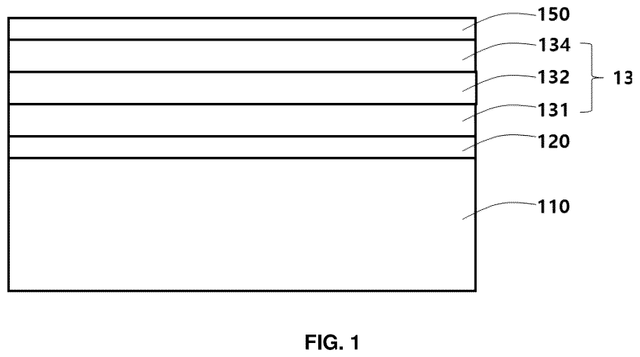

Referring to FIG. 1, a method for manufacturing a GaN HEMT power semiconductor epitaxy wafer having a high-quality GaN channel region through growth temperature modulation according to the present embodiment sequentially grows an AlN nucleation region (120), a first GaN channel region (131), a second GaN channel region (132), a third GaN channel region (134), and an AlGaN barrier region (150).

The AlN nucleation region (120) is formed on a growth substrate (110), and is typically formed within a MOCVD chamber.

The growth substrate (110) may be, for example, a silicon (Si) substrate, a silicon carbide (SiC) substrate, or an aluminum oxide substrate. The aluminum oxide substrate may be, for example, an Al₂O₃ substrate.

It is preferable that the silicon (Si) growth substrate has a (111) plane as the growth plane, which has a high atomic filling rate like the group III nitride crystal structure (HCP), rather than the (100,110) plane.

For the silicon carbide (SiC) growth substrate, the 4H-SiC growth substrate, which has the same crystal structure as the group III nitride crystal structure (HCP) and the smallest lattice constant difference, is preferred, and it is preferable that the Si polar face is used as the growth plane.

The AlN nucleation region (120) is a region for high-quality formation of the subsequently grown first, second, and third GaN channel regions (131, 132, 134) and the AlGaN barrier region (150), and has the function of controlling stress transferred to the subsequently grown region.

It is preferable that the AlN nucleation region (120) be formed of an AlN thin film layer having a smooth surface with aluminum (Al) surface polarity.

The GaN channel region (130) is provided with three regions having different growth temperatures, namely, the first, second, and third GaN channel regions (131, 132, and 134).

In addition, a SiNx region (140) may be placed between the first and second GaN channel regions (131, 132), which will be described after the description of the first, second, and third GaN channel regions (131, 132, 134).

The first GaN channel region (131) is formed on the AlN nucleation region (120) and grown at a first growth temperature higher than the growth temperature of the AlN nucleation region (120). It is defined as the ‘first high-temperature growth region’.

The growth temperature of the AlN nucleation region (120) is 850 to 1100° C., the first growth temperature is 1050 to 1100° C., and it is preferable that the first GaN channel region (131) is grown with GaN in a 2-dimensional growth mode at the first growth temperature.

The thickness is preferably 20 to 100 nm.

At this time, the growth pressure is preferably 150 to 250 torr, the V/III ratio is preferably 500 to 1000, and the growth atmosphere is preferably a H2 rich atmosphere. It is also desirable to maintain the same in the growth of the second and third GaN channel regions (132, 134) and the MT-GaN channel region (133) described later.

The second GaN channel region (132) is formed on the first GaN channel region (131) and is grown at a second growth temperature lower than the first growth temperature.

The second growth temperature is 750 to 850° C. and is defined as a ‘low-temperature growth region’.

The thickness is preferably 5 to 20 nm.

The second GaN channel region (132) is intended to relieve stress generated by the high-temperature first growth temperature in the growth of the first GaN channel region (131), increase the thickness, and minimize crystal defects.

The third GaN channel region (134) is formed on the second GaN channel region (132) and is grown at a third growth temperature equal to or higher than the first growth temperature.

The third growth temperature is 1050 to 1100° C. and is defined as a ‘second high-temperature growth region’.

The thickness is 75 nm or more, but it is preferable that the total thickness of the first, second, and third GaN channel regions (131, 132, 134) is 500 nm or less.

The third GaN channel region (134) has a function of improving the crystallinity of the first, second, and third GaN channel regions (131, 132, 134) or the first, second, third, and MT GaN channel regions (131, 132, 133, 134) described below.

An AlGaN barrier region (150) is grown on the third GaN channel region (134).

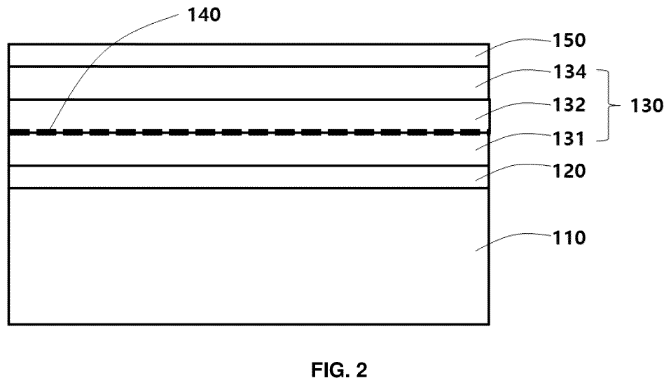

Next, referring to FIG. 2, the present embodiment may add a SiNₓ region (140).

The SiNₓ region (140) is formed to be inserted between the first GaN channel region (131) and the second GaN channel region (132).

The SiNₓ region (140) has the function of masking crystal defects on the surface of the first GaN channel region (131).

The thickness is preferably 5 to 20 nm.

The SiNₓ region (140) is formed by stopping the growth of the first GaN channel region (131) and supplying SiH₄ or Si₂H₆, which is a Si source, under conditions in which ammonia (NH₃), which is a nitrogen source, is supplied, thereby growing nanoscale SiNₓ in a 3-dimensional growth mode.

Even when the SiNx region (140) is added, it is preferable that the total thickness including the first, second, and third GaN channel regions (131, 132, 134) be formed to be 500 nm or less.

According to the present embodiment, after forming a first GaN channel region (131) as a ‘first high-temperature growth region’, a second GaN channel region (132) is grown as a ‘low-temperature growth region’ (or a ‘low-temperature growth region’ and a ‘medium-temperature growth region’ described below), and then a third GaN channel region (134) is grown as a ‘second high-temperature growth region’ to finally complete the GaN channel region. As a result, the crystal quality of the GaN channel region can be improved and stress can be relieved.

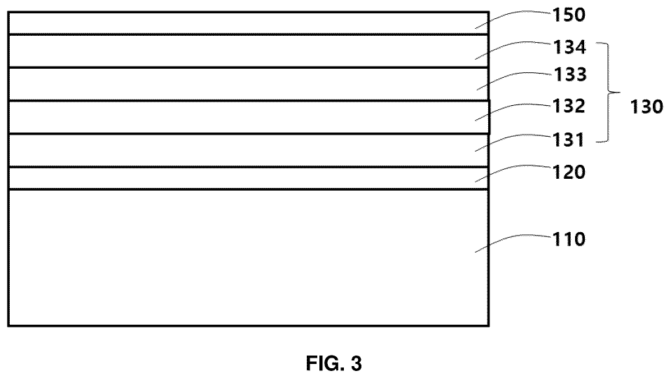

Referring to FIG. 3, the other configurations are the same as the previously described embodiment, but there is a difference in that an MT-GaN channel region (133) is added.

The MT-GaN channel region (133) is formed to be inserted between the second GaN channel region (132) and the third GaN channel region (134), and is grown at an MT growth temperature that is higher than the second growth temperature and lower than the third growth temperature.

The MT growth temperature is 850˜950° C., and is defined as the ‘medium-temperature growth region’.

According to this embodiment, by adding an “medium-temperature growth region’ between the ‘low temperature growth region’ and the ‘second high temperature growth region’, the change in growth temperature can be reduced, thereby improving the crystal quality of the GaN channel region and further enhancing the stress relief effect.

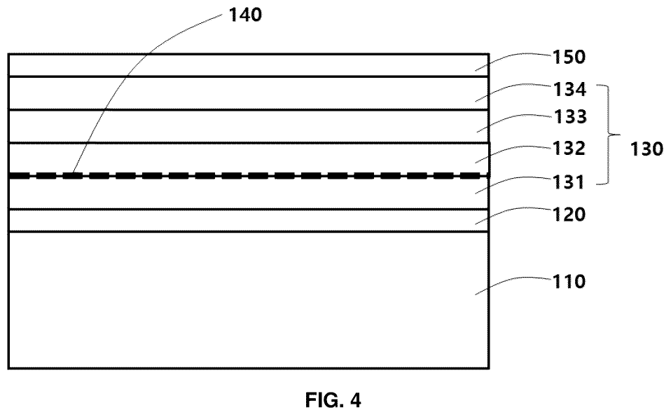

FIG. 4 is an example of the embodiment of FIG. 3 with the addition of the SiNx region (140).

Here, the SiNx region (140) is formed prior to the growth of the ‘low-temperature growth region’ and has the function of masking crystal defects on the surface of the first GaN channel region (131).

Below, we describe additional components that are added to make the effects of the embodiments described above more evident or to improve them.

In the present invention, it is preferable that the AlN nucleation region (120) be provided with an AlN thin film layer having a smooth surface having aluminum (Al) surface polarity.

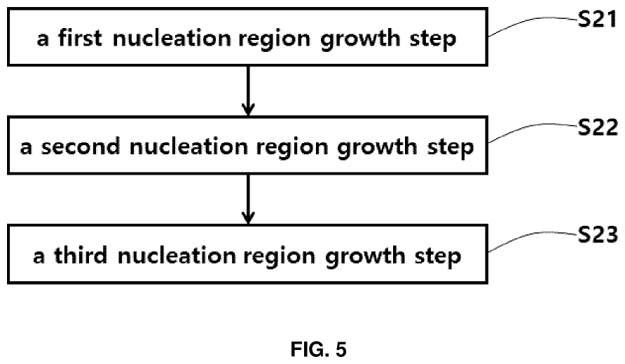

Referring to FIG. 5, the step of growing the AlN nucleation region (120) is performed in three steps: a first nucleation region growth step (S21), a second nucleation region growth step (S22), and a third nucleation region growth step (S23).

The first nucleation region growth step (S21) is a step in which only TMAl or TEAl, which is an Al source, is supplied without supplying ammonia (NH₃), which is a nitrogen source, at a temperature (850 to 950° C.) lower than the growth temperature (950 to 1050° C.) of the AlN nucleation region (120).

Supplying only the Al source without the nitrogen source in the first nucleation region growth step (S21) is to suppress the nitride parasitic reaction in the air inside the MOCVD chamber before reaching the surface of the growth substrate.

The second nucleation region growth step (S22) is a step in which ammonia (NH₃), a nitrogen source, is supplied to the first nucleation region growth step (S21) and AlN is grown in a 3-dimensional growth mode.

The purpose of growing AlN in a 3-dimensional growth mode in the second nucleation region growth step (S22) is to act as a buffer between the growth substrate and the subsequently grown epitaxial layer.

The third nucleation region growth step (S23) is a step of increasing the temperature to the growth temperature (950 to 1050° C.) of the AlN nucleation region (120) and growing AlN in a 2-dimensional growth mode.

The purpose of growing AlN in a 2-dimensional growth mode in the third nucleation region growth step (S23) is to promote the surface shape of the AlN nucleation region to have a smooth and uniform Al surface polarity and to suppress the formation of surface crystal defects in the shape of V-pits.

2D growth mode (2-dimensional growth mode) is to grow AlN preferentially in the horizontal direction, and can be achieved through pulsed NH₃ source supply.

3D growth mode (3-dimensional growth mode) is to grow AlN preferentially in the vertical direction, and can be achieved through continuous NHs source supply.

According to the present invention described above, a high-quality GaN channel layer can be secured while having a thin epitaxy thickness of 500 nm or less.

As a result, the buffer region of a conventional high-resistance GaN (Fe or C doping) that requires a thick thickness of about 1.5 μm can be eliminated, thereby maximizing the heat dissipation characteristics of the GaN HEMT device.

What is claimed is:

1. Method for manufacturing GaN HEMT power semiconductor epitaxial wafers with high-quality GaN channel region through growth temperature modulation, comprising:
a step of growing an AlN nucleation region formed on a growth substrate;
a step of growing a first GaN channel region formed on the AlN nucleation region at a first growth temperature higher than a growth temperature of the AlN nucleation region;
a step of growing a second GaN channel region formed on the first GaN channel region at a second growth temperature lower than the first growth temperature;
a step of growing a third GaN channel region formed on the second GaN channel region at a third growth temperature equal to or higher than the first growth temperature; and
a step of forming an AlGaN barrier region on the third GaN channel region.

2. The method of claim 1, further comprising:
a step of growing an MT-GaN channel region at an MT growth temperature that is higher than the second growth temperature and lower than the third growth temperature,
wherein the MT-GaN channel region is formed to be inserted between the second GaN channel region and the third GaN channel region.

3. The method of claim 1, further comprising:
a step of forming a SiNₓ region that is formed to be inserted between the first GaN channel region and the second GaN channel region, and that stops growth of the first GaN channel region and masks crystal defects on a surface of the first GaN channel region.

4. The method of claim 3, wherein the step of forming the SiNₓ region is a step of forming nanoscale SiNₓ in a 3-dimensional growth mode by stopping the growth of the first GaN channel region and supplying SiH₄ or Si₂H₆, which is a Si source, under conditions in which ammonia (NH₃), which is a nitrogen source, is supplied.

5. The method of claim 1, wherein the step of growing the AlN nucleation region comprises:
a first nucleation region growth step of supplying only TMAl or TEAl as an Al source without supplying ammonia (NH₃) as a nitrogen source at a temperature lower than a growth temperature of the AlN nucleation region;
a second nucleation region growth step of supplying ammonia (NH₃) as a nitrogen source to the first nucleation region growth step and growing AlN in a 3-dimensional growth mode; and
a third nucleation region growth step of increasing the temperature to the growth temperature of the AlN nucleation region and growing AlN in a 2-dimensional growth mode.

6. The method of claim 1, wherein the step of growing the first GaN channel region is to grow GaN in a 2-dimensional growth mode at the first growth temperature.

7. The method of claim 1, wherein the step of growing the second GaN channel region is to relieve stress generated by the first growth temperature, which is a high temperature, in the growth of the first GaN channel region, increase the thickness, and minimize crystal defets.

8. The method of claim 1, wherein the step of growing the third GaN channel region improves the crystallinity of the first, second, and third GaN channel regions.

9. The method of claim 1, wherein the first growth temperature is 1050 to 1100° C., the second growth temperature is 750 to 850° C., and the third growth temperature is 1050 to 1100° C.

10. The method of claim 2, further comprising:
a step of forming a SiNₓ region that is formed to be inserted between the first GaN channel region and the second GaN channel region, and that stops growth of the first GaN channel region and masks crystal defects on a surface of the first GaN channel region.

11. The method of claim 10, wherein the step of growing the AlN nucleation region comprises:
a first nucleation region growth step of supplying only TMAl or TEAl as an Al source without supplying ammonia (NH₃) as a nitrogen source at a temperature lower than a growth temperature of the AlN nucleation region;
a second nucleation region growth step of supplying ammonia (NH₃) as a nitrogen source to the first nucleation region growth step and growing AlN in a 3-dimensional growth mode; and
a third nucleation region growth step of increasing the temperature to the growth temperature of the AlN nucleation region and growing AlN in a 2-dimensional growth mode.

12. The method of claim 10, wherein the step of forming the SiNₓ region is a step of forming nanoscale SiNₓ in a 3-dimensional growth mode by stopping the growth of the first GaN channel region and supplying SiH₄ or Si₂H₆, which is a Si source, under conditions in which ammonia (NH₃), which is a nitrogen source, is supplied.

13. The method of claim 2, wherein the first growth temperature is 1050 to 1100° C., the second growth temperature is 750 to 850° C., the third growth temperature is 1050 to 1100° C., and the MT growth temperature is 850 to 950° C.
